(19) United States
(12) Patent Application Publication
(10) Pub. No.: US 2011/0283165 A1
(43) Pub. Date: Nov. 17, 2011

(54) MEMORY SYSTEM AND DATA TRANSFER METHOD OF THE SAME

(76) Inventor: Takahide NISHIYAMA, Yokohama-shi (JP)

(21) Appl. No.: 13/028,788

(22) Filed: Feb. 16, 2011

(30) Foreign Application Priority Data
May 14, 2010 (JP) 2010-112470

(51) Int. Cl. H03M 13/05; G06F 11/10

(52) U.S. Cl. 714/773; 714/E11.035

(57) ABSTRACT

According to one embodiment, a memory system includes a nonvolatile memory, a first buffer configured to temporarily store data transferred from the nonvolatile memory, a correction circuit configured to correct an error of data transferred from the first buffer, a second buffer configured to temporarily store data transferred from the correction circuit, a bus configured to receive data transferred from the second buffer, a command sequencer group configured to issue commands for data transfer between the nonvolatile memory and the bus, a command decoder group configured to decode the commands, and generate control signals for controlling data transfer, a CPU connected to the bus, and an interrupt circuit configured to generate an interrupt in the CPU if a read error occurs because of an error correction failure. The command sequencer group continues data transfer from the nonvolatile memory even when an interrupt occurs because of the read error.

### CROSS-REFERENCE TO RELATED APPLICATIONS

This application is based upon and claims the benefit of priority from Japanese Patent Application No. 2010-112470, filed May 14, 2010; the entire contents of which are incorporated herein by reference.

### FIELD

Embodiments described herein relate generally to a memory system and a data transfer method of the same.

### BACKGROUND

A NAND flash memory as a kind of an electrically erasable programmable read-only memory (EEPROM) that electrically writes and erases data is known as a nonvolatile semiconductor memory.

In a memory system including this NAND flash memory, a plurality of modules are connected to one system bus (or a plurality of system buses), and data transfer operations between these modules are switched by the intervention of firmware processing performed by a central processing unit (CPU). Whenever inter-module data transfer is complete, therefore, an interrupt of notifying the completion of the transfer operation occurs, and the next transfer operation can be performed after the next operation setting is performed by the firmware processing.

Accordingly, if an error correction circuit for correcting an error of data read from the NAND flash memory exists or a plurality of memory buffers exist, the number of times of the process of switching inter-module data transfer operations increases. Consequently, very many interrupts occur whenever inter-module transfer is complete. In other words, the intervention time of the firmware processing becomes very long. This extremely prolongs the latency of data transfer.

### BRIEF DESCRIPTION OF THE DRAWINGS

FIG. 1 is a flowchart showing the read operation of a memory system according to a comparative example;

FIG. 2 is a block diagram showing the configuration of a memory system 10 according to an embodiment;

FIG. 3 is a block diagram showing the arrangement of a data transfer controller 13;

FIG. 4 is a view for explaining data transfer to which command sequencers SEQ are assigned;

FIG. 5 is a circuit diagram showing the arrangement of a part of a sequencer control circuit 30;

FIG. 6 is a schematic view for explaining a data structure;

FIG. 7 is a flowchart showing the operation of a controller 12; and

FIG. 8 is a timing chart showing the operations of command sequencers SEQ1 to SEQ4.

### DETAILED DESCRIPTION

In general, according to one embodiment, there is provided a memory system comprising:

a nonvolatile memory configured to store data;

a first buffer configured to temporarily store data transferred from the nonvolatile memory;

a correction circuit configured to correct an error of data transferred from the first buffer;

a second buffer configured to temporarily store data transferred from the correction circuit;

a bus configured to receive data transferred from the second buffer;

a command sequencer group configured to issue commands for data transfer between the nonvolatile memory and the bus;

a command decoder group configured to decode the commands, and generate control signals for controlling data transfer;

a CPU connected to the bus; and

an interrupt circuit configured to generate an interrupt in the CPU if a read error occurs because of an error correction failure,

wherein the command sequencer group continues data transfer from the nonvolatile memory even when an interrupt occurs because of the read error.

The embodiments will be described hereinafter with reference to the accompanying drawings. In the description which follows, the same or functionally equivalent elements are denoted by the same reference numerals, to thereby simplify the description.

### COMPARATIVE EXAMPLE

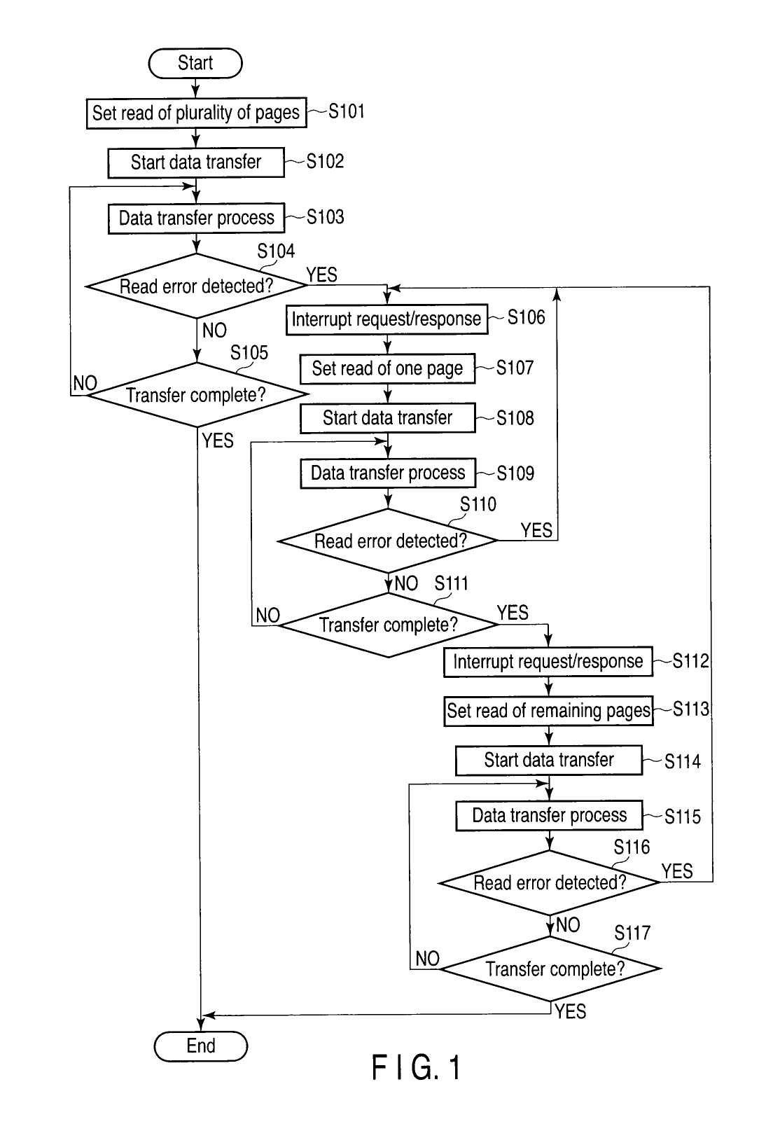

FIG. 1 is a flowchart showing the read operation of a memory system according to a comparative example. The memory system includes a NAND flash memory and controller. The controller includes a CPU and data transfer controller.

When reading data from the NAND flash memory, read setting for reading a plurality of pages is first performed by firmware processing (step S101), and the CPU instructs the data transfer controller to start data transfer (step S102). When the data transfer is started, hardware processing is performed to transfer data read from the NAND flash memory to an ECC decoder where error correction is performed, and transfer the data to the inside of the system if a normal data is returned from the ECC decoder (step S103).

If a read error occurs, an interrupt is generated to stop the data transfer (step S104). An interrupt response process is performed by firmware processing (step S106), and the CPU checks the cause of the generated interrupt. If it is determined that the cause is the read error interrupt, the CPU performs read setting required for a retry operation, for example, the corresponding retry page position, frame position, and number of transfer pages (only one page) (step S107), and restarts the data transfer (steps 5108 and S109). While this setting is performed by firmware processing, internal sequencers and the like are stopped (reset).

In this retry operation, data transfer of only one page can be performed. If the data transfer of one page is complete without any read error (step S111), a transfer completion interrupt occurs, and the operation switches to the firmware processing again. An interrupt response process is performed by the firmware processing (step S112), and the CPU checks the cause of the generated interrupt. If it is determined that the data transfer of one page is complete, the CPU performs read setting required for the transfer of remaining pages (step S113). After that, the CPU starts data transfer (step S114), and continues the data transfer process (step S115). If a read error occurs after that, the transfer operation is repeated following the same procedure as above.

In this comparative example, if an interrupt occurs because of a read error, the transfer of a plurality of initially set pages is performed while the retry operation of data transfer of one page and the data transfer operation of remaining pages are performed. Consequently, the firmware processing intervenes many number of times, and a data transfer page dividing process or the like is necessary. That is, the latency of data transfer prolongs because a read error occurs.

### Embodiment

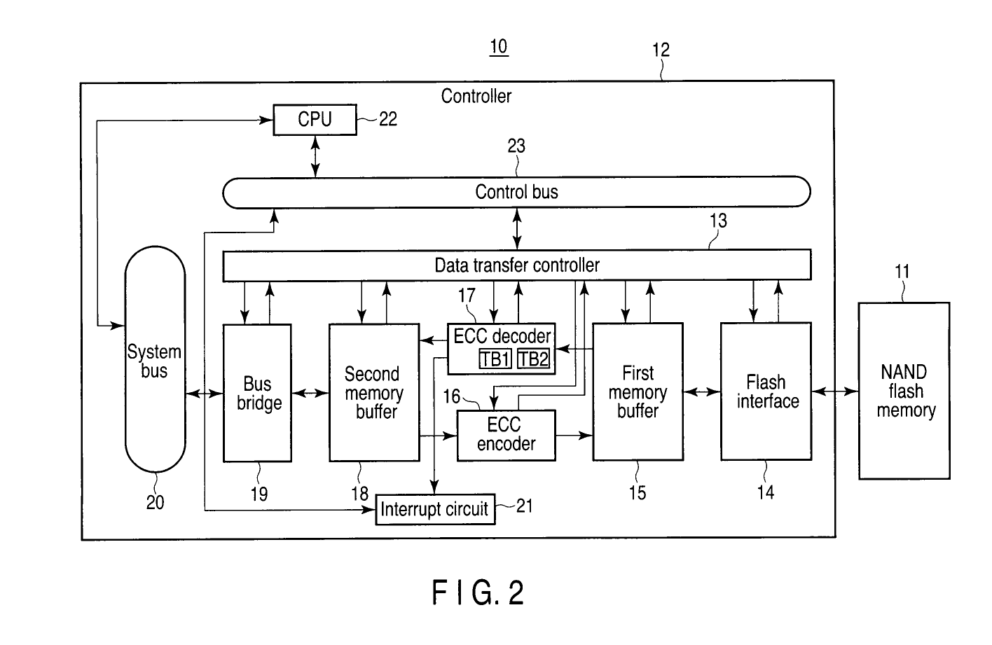

FIG. 2 is a block diagram showing the configuration of a memory system 10 according to an embodiment. The memory system 10 comprises a NAND flash memory 11 as a nonvolatile semiconductor memory, and a controller 12 for controlling the NAND flash memory 11.

The NAND flash memory 11 comprises a plurality of blocks each of which is the unit of data erase. Each block is formed by arranging a plurality of flash memory cells in a matrix, and comprises a plurality of pages each having a plurality of bits. The NAND flash memory 11 performs data read and write for each page. In addition, the NAND flash memory 11 comprises a column decoder for selecting a column of a memory cell array, a row decoder for selecting a row of the memory cell array, a sense amplifier circuit for reading data from a memory cell, and a data cache for holding read data and write data.

The controller 12 comprises a data transfer controller 13, flash interface 14, first memory buffer 15, error checking and correcting (ECC) encoder 16, ECC decoder 17, second memory buffer 18, bus bridge 19, system bus 20, interrupt circuit 21, central processing unit (CPU) 22, and control bus 23.

The CPU 22 is connected to the system bus 20 and control bus 23. The CPU 22 comprehensively controls modules in the memory system 10 by using firmware (FW) stored in a ROM (not shown) connected to the system bus 20. The CPU 22 sends a control signal to the data transfer controller 13 via the control bus 23, and exchanges data with various modules via the system bus 20. The module is a functional unit for implementing a desired operation and function. In this embodiment, the module is each functional block shown in FIG. 2. Note that although not shown, the system bus 20 is also connected to, for example, a host interface, and a random access memory (RAM) necessary for the operation of the memory system 10.

The flash interface 14 executes interface processing with respect to the NAND flash memory 11. More specifically, the flash interface 14 executes data erase, write, and read with respect to the NAND flash memory 11. For this purpose, the flash interface 14 supplies a command and address to the NAND flash memory 11, and exchanges write data and read data with the NAND flash memory 11.

The ECC encoder 16 receives write data, and generates an error correction code (parity code) for the write data. Also, the ECC encoder 16 generates a parity code by using a predetermined data size as a calculation unit. This parity code is added to the write data, and written together with the write data to the NAND flash memory 11. In this embodiment, a data string as an ECC calculation unit and the parity code will collectively be called a frame.

The ECC decoder 17 receives read data, and corrects an error of the read data by using the parity code added to the read data. The ECC decoder 17 can use two kinds of correction methods in an error correction process using the parity code. To implement error correction by the two kinds of correction methods, the ECC decoder 17 includes two kinds of ECC parameter tables TB1 and TB2 corresponding to the two kinds of correction methods. The two kinds of correction methods can be switched by switching two kinds of ECC parameter tables TB1 and TB2 of the ECC decoder 17. The difference between the two kinds of correction methods can be the difference between parity calculation methods (e.g., the likelihood ratio), and can also be the difference between error correction capabilities. The ECC decoder 17 having the arrangement like this can increase the error correction probability by switching the correction methods in accordance with the characteristics of the NAND flash memory 11.

The first memory buffer 15 temporarily stores read data from the NAND flash memory 11, or write data to which the parity code is added by the ECC encoder 16 immediately before the data is written in the NAND flash memory 11. The second memory buffer 18 temporarily stores write data immediately before the parity code is added, or read data corrected by the ECC decoder 17. Each of the memory buffers 15 and 18 is, for example, a RAM. The bus bridge 19 executes interface processing between the second memory buffer 18 and system bus 20.

The interrupt circuit 21 requests the CPU 22 to generate an interrupt. For example, if a read error occurs because of, for example, an error correction failure in an operation of reading data from the NAND flash memory 11, the interrupt circuit 21 notifies the CPU 22 of the occurrence of the read error and the frame number of the error correction failure.

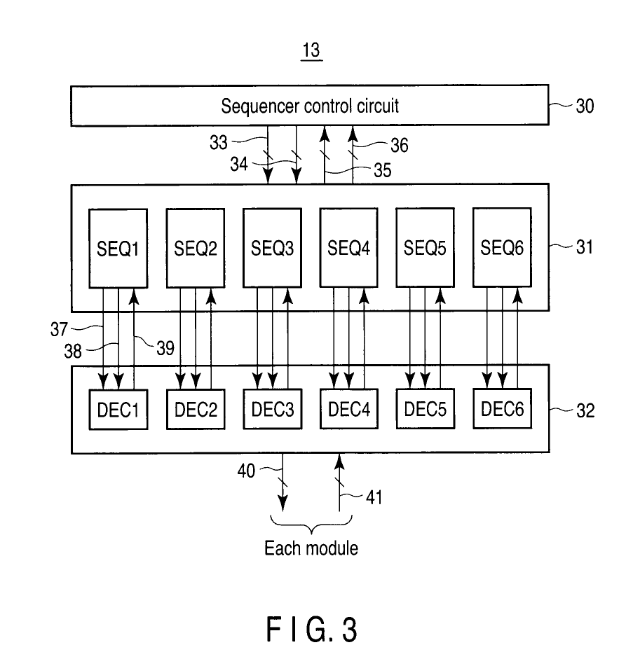

The data transfer controller 13 executes a data transfer process between the NAND flash memory 11 and system bus 20 by hardware processing. Since this saves the CPU 22 the trouble of performing the data transfer process between the NAND flash memory 11 and system bus 20, the processing load on the CPU 22 can be reduced. FIG. 3 is a block diagram showing the arrangement of the data transfer controller 13.

The data transfer controller 13 comprises a command sequencer group 31, a sequencer control circuit 30 for controlling the command sequencer group 31, and a command decoder group 32.

The command sequencer group 31 includes command sequencers SEQ equal in number to inter-module data transfer processes. As an example, FIG. 3 shows six command sequencers SEQ1 to SEQ6. The command sequencers SEQ each issue a specific command sequence for controlling inter-module processing based on an operation mode, and the command sequence is independently generated for each inter-module processing. The modules execute data transfer processes corresponding to the command sequences in parallel.

Each command sequencer SEQ issues a command sequence required for a corresponding inter-module data transfer process. That is, whenever receiving a ready signal 39 from a command decoder DEC, the command sequencer SEQ sends a command 37 to the command decoder DEC. The ready signal 39 indicates that a series of operations corresponding to the command 37 is complete, and is asserted when the series of operations are complete. In addition to the issued command 37, the command sequencer SEQ sends a valid signal 38 indicating whether the command 37 is valid, to the command decoder DEC.

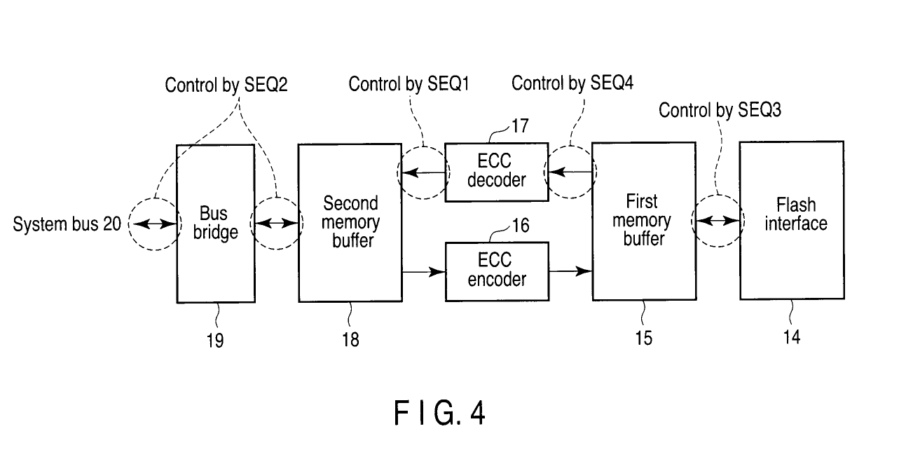

FIG. 4 is a view for explaining data transfer to which the command sequencers SEQ are assigned. Command sequencers that operate in data read are SEQ1 to SEQ4. Command sequencers SEQ5 and SEQ6 operate in, for example, data write.

Command sequencer SEQ3 controls data transfer from the flash interface 14 to the first memory buffer 15, and data transfer in the opposite direction. Command sequencer SEQ4 controls data transfer from the first memory buffer 15 to the ECC decoder 17, and data transfer in the opposite direction. Command sequencer SEQ1 controls data transfer from the ECC decoder 17 to the second memory buffer 18, and data transfer in the opposite direction. Command sequencer SEQ2 controls data transfer from the second memory buffer 18 to the system bus 20 via the bus bridge 19, and data transfer in the opposite direction.

The sequencer control circuit 30 comprises a register to be set by the CPU 22, and determines a command sequencer SEQ to be operated, based on an operation mode set in this register. For this control, the sequencer control circuit 30 generates a start signal 33 for starting the operation of the command sequencer SEQ and a stop signal 34 for stopping the operation of the command sequencer SEQ, and sends the start signal 33 and stop signal 34 to the command sequencer SEQ. Also, the sequencer control circuit 30 determines the transmission timing of the start signal 33 and stop signal 34 based on a valid signal 35 and a frame number 36 received from the command sequencer SEQ and an interrupt request signal ECC_REQ received from the ECC decoder 17.

The command decoder group 32 comprises a plurality of command decoders DEC corresponding to the plurality of command sequencers SEQ. Each command decoder DEC decodes the command 37 sent from the command sequencer SEQ. If the valid signal 38 sent together with the command 37 is asserted, the command decoder DEC generates a control signal 40 for controlling inter-module data transfer, in accordance with the command 37. The control signal 40 is sent to the data transmission source (source side) and the data transmission destination (destination side). The command decoder DEC can check the state of a module by receiving a state flag signal 41 from the module. When completing processing corresponding to one command 37 contained a command sequence, the command decoder DEC returns the ready signal 39 to the command sequencer SEQ, and receives the next command from the command sequencer SEQ.

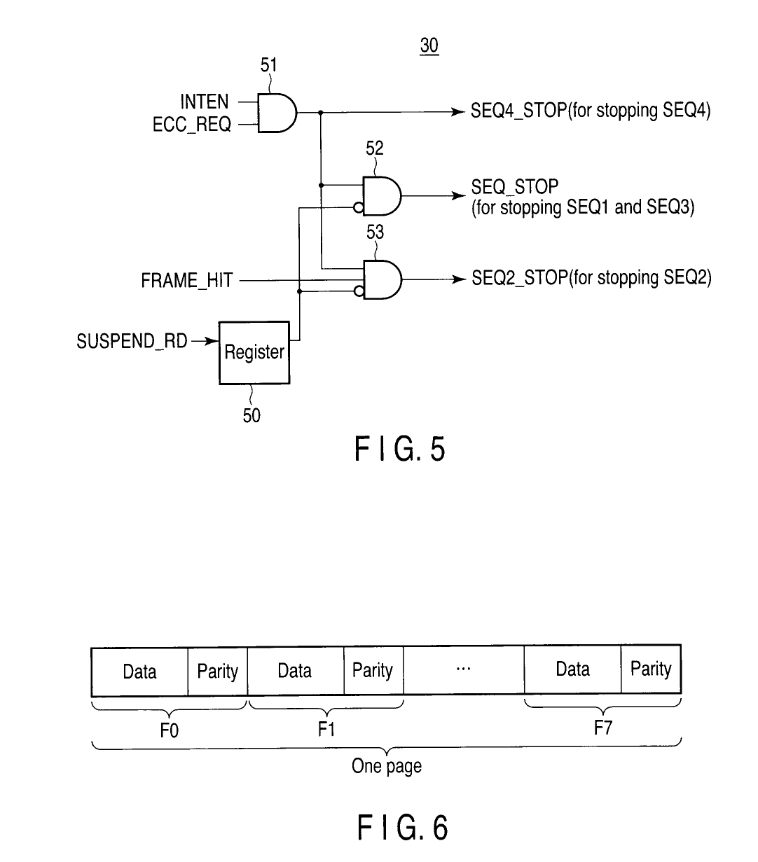

FIG. 5 is a circuit diagram showing the arrangement of a part of the sequencer control circuit 30. FIG. 5 specifically shows a circuit part for generating a stop signal for stopping the command sequencer SEQ. The sequencer control circuit 30 comprises a register 50 and three AND gates 51 to 53.

The register 50 stores data SUSPEND_RD. The CPU 22 sets the data in the register 50. The data SUSPEND_RD is used to invalidate the process of temporarily stopping some command sequencers in a read operation. If the data in the register 50 is “1”, an operation mode of invalidating the process of temporarily stopping some command sequencers (in this embodiment, command sequencers SEQ1 to SEQ3) is executed.

The interrupt circuit 21 inputs an interrupt enable signal INTEN to the first input terminal of the

AND gate 51, and the ECC decoder 17 inputs an interrupt request signal ECC_REQ to the second input terminal of the AND gate 51. The AND gate 51 outputs a stop signal SEQ4_STOP for stopping command sequencer SEQ4. The interrupt enable signal INTEN is used to enable an interrupt process. When the interrupt enable signal INTEN is high, the interrupt process is enabled. The CPU 22 sets the interrupt enable signal INTEN in a register (not shown) of the interrupt circuit 21. The interrupt request signal ECC_REQ is made high when the ECC decoder 17 cannot correct an error, i.e., when an interrupt is necessary. Accordingly, stop signal SEQ4_STOP is asserted (made high) when the interrupt process is enabled and an interrupt resulting from ECC is requested.

The AND gate 51 supplies the output to the first input terminal of the AND gate 52, and the register 50 supplies the output to the second input terminal (active low) of the AND gate 52. The AND gate 52 outputs a stop signal SEQ_STOP for stopping command sequencers SEQ1 and SEQ3. Therefore, the stop signal SEQ_STOP is asserted (made high) when stop signal SEQ4_STOP goes high and the temporary stopping process is invalid.

The AND gate 51 supplies the output to the first input terminal of the AND gate 53, the interrupt circuit 21 inputs a frame hit signal FRAME_HIT to the second input terminal of the AND gate 53, and the register 50 supplies the output to the third input terminal (active low) of the AND gate 53. The AND gate 53 outputs a stop signal SEQ2_STOP for stopping command sequencer SEQ2. The frame hit signal FRAME_HIT goes high when a frame currently being transferred by command sequencer SEQ2 matches a frame in which an error has occurred. Accordingly, stop signal SEQ2_STOP is asserted (made high) after data before the error frame is transferred. Note that in this embodiment, when the output from the register 50 is high, stop signal SEQ2_STOP is kept negated (low) regardless of the state of the frame hit signal FRAME_HIT.

### (Operation)

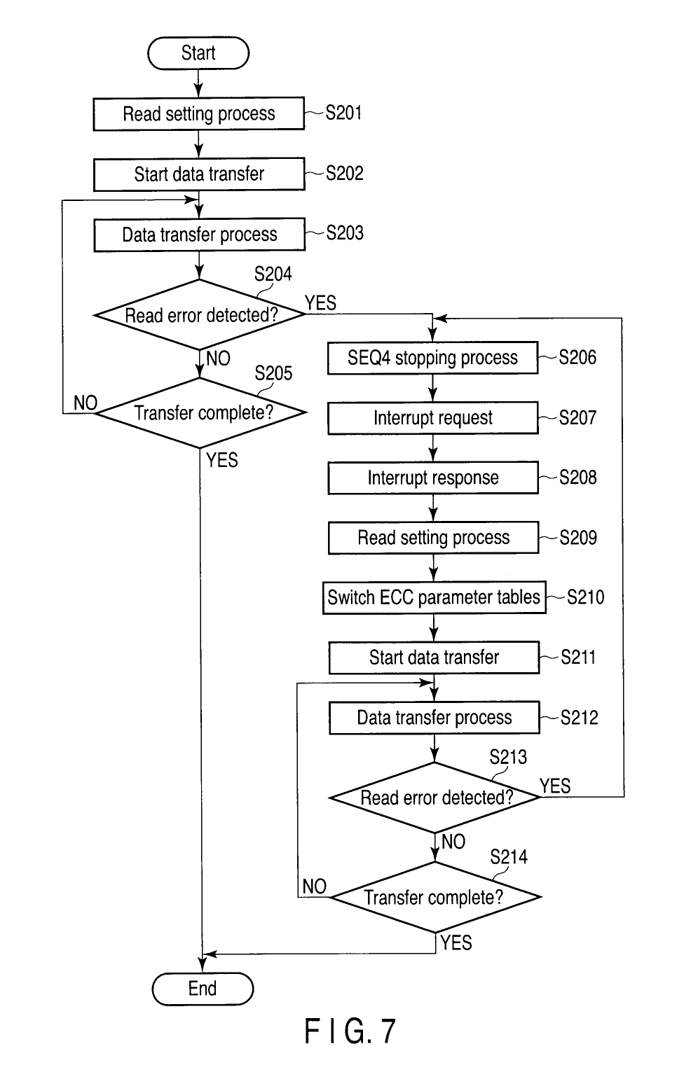

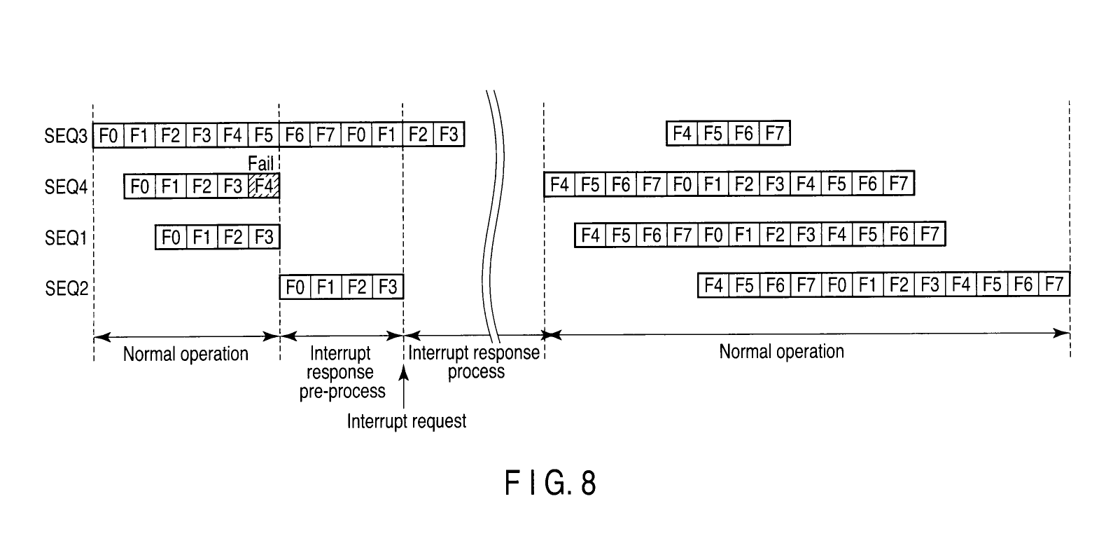

Next, the operation of the memory system 10 configured as above will be explained. In this embodiment, as shown in FIG. 6, one page as the read unit of the NAND flash memory 11 comprises eight frames F0 to F7. FIG. 7 is a flowchart showing the operation of the controller 12. FIG. 8 is a timing chart showing the operations of command sequencers SEQ1 to SEQ4.

First, the CPU 22 performs read setting necessary to read data from the NAND flash memory 11, in the data transfer controller 13 by firmware processing (step S201). The read setting includes the page position, frame position, ECC parameter table, and number of transfer pages. Also, in the stage of the read setting, the CPU 22 sets data “1” in the register shown in FIG. 5, thereby invalidating the process of temporarily stopping command sequencers SEQ1 to SEQ3. If a read error is detected, all command sequencers are stopped in the comparative example. In this embodiment, however, control can be performed so as not to stop the command sequencers by invalidating the temporary stopping process.

Subsequently, the CPU 22 instructs the data transfer controller 13 to start data transfer (step S202). In response to this instruction, the data transfer controller 13 executes the process of transferring data from the NAND flash memory 11 to the system bus 20 (step S203). This data transfer is processed in the order of SEQ3→SEQ4→SEQ1→SEQ2.

That is, the flash interface 14 supplies a command and address to the NAND flash memory 11, and reads data for each page from the NAND flash memory 11. Command sequencer SEQ3 issues a command sequence for transferring the data from the flash interface 14 to the first memory buffer 15. The command sequence is supplied together with valid signals to command decoder DEC3. Based on the command sequence, command decoder DEC3 sends control signals to the flash interface 14 and first memory buffer 15. Based on the control signals, data transfer is performed between the flash interface 14 and first memory buffer 15.

Then, command sequencer SEQ4 issues a command sequence for transferring the data from the first memory buffer 15 to the ECC decoder 17. The command sequence is supplied together with valid signals to command decoder DEC4. Based on the command sequence, command decoder DEC4 sends control signals to the first memory buffer 15 and ECC decoder 17. Based on the control signals, data transfer is performed between the first memory buffer 15 and ECC decoder 17. The ECC decoder 17 performs error correction for each frame by using the ECC parameter table TB1.

After that, command sequencer SEQ1 issues a command sequence for transferring the data from the ECC decoder 17 to the second memory buffer 18. The command sequence is supplied together with valid signals to command decoder DEC1. Based on the command sequence, command decoder DEC1 sends control signals to the ECC decoder 17 and second memory buffer 18. Based on the control signals, data transfer is performed between the ECC decoder 17 and second memory buffer 18.

Subsequently, command sequencer SEQ2 issues a command sequence for transferring the data from the second memory buffer 18 to the system bus 20 via the bus bridge 19. The command sequence is supplied together with valid signals to command decoder DEC2. Based on the command sequence, command decoder DEC2 sends control signals to the second memory buffer 18 and bus bridge 19. Based on the control signals, data transfer is performed between the second memory buffer 18 and system bus 20.

If the ECC decoder 17 corrects an error in the transfer data or if no error is detected in the transfer data, the data transfer is complete (step S205).

On the other hand, if an error exceeding the number of bits correctable by the ECC decoder 17 occurs in a frame, the error is regarded as a read error (step S204). In this case, the CPU 22 is requested to generate an interrupt in order to retry the transfer of the frame having caused the read error.

FIG. 8 exemplarily shows a data transfer operation when error correction fails in frame F4 of the first page and a read error occurs. Before the interrupt request, command sequencer SEQ2 executes a transfer operation (interrupt response pre-process) for frames F0 to F3 in which error correction has normally been performed.

Subsequently, the sequencer control circuit 30 stops command sequencer SEQ4 (step S206). That is, in

FIG. 5, both the interrupt enable signal INTEN and interrupt request signal ECC_REQ go high, and stop signal SEQ4_STOP goes high. Also, the stop signal for command sequencers SEQ1 to SEQ3 is negated (low). Accordingly, command sequencers SEQ1 to SEQ3 keep operating.

Then, the interrupt circuit 21 requests the CPU 22 to generate an interrupt (step S207). In response to this interrupt request, the CPU 22 performs an interrupt response process (firmware processing), i.e., checks the cause of the generated interrupt (step S208). If it is determined that the cause is a read error interrupt, the CPU 22 performs a read setting process (step S209). In addition to this read setting process, the CPU 22 switches the ECC parameter tables in the ECC decoder 17 (step S210). The read setting includes the corresponding retry page position and frame position. The rest of the set contents need not be changed because the modules keep operating by the initially set contents. More specifically, command sequencers SEQ1 to SEQ3 need not be reset even when an interrupt occurs, and only command sequencer SEQ4 is reset. Thus, the CPU 22 does not reset (initialize) the command sequencer group 31 even when an interrupt occurs.

After that, the CPU 22 instructs the data transfer controller 13 to start data transfer (step S211). When data transfer is restarted in this stage, the data can be transferred until a predetermined page unless a read error occurs midway along the process. This avoids the intervention of extra firmware processing by the CPU 22. In response to this instruction, the data transfer controller 13 executes the process of transferring data from the NAND flash memory 11 to the system bus 20 (step S212). The process from this step is the same as in steps S204 and S205.

As shown in FIG. 8, after the data transfer of frame F3 is complete, command sequencers SEQ1 and SEQ2 wait for the transfer of frame F4. Command sequencer SEQ3 keeps accessing the NAND flash memory 11 as long as pre-read is possible. When frame F3 of the second page is transferred, the first memory buffer 15 becomes full, and command sequencer SEQ3 waits for the transfer of frame F4 of the second page. Even when the interrupt response process is started, therefore, command sequencer SEQ3 is accessing the NAND flash memory 11. Consequently, the latency can be improved by the parallel processing of the interrupt response (firmware processing) and the pre-read (hardware processing) of the NAND flash memory 11. In this case, a transfer penalty caused by a read error is zero if the condition “firmware processing time<hardware processing time”.

Note that if an interrupt occurs because of a read error, it is also possible to perform control so as to stop the operations of all command sequencers SEQ1 to SEQ4. In this case, the CPU 22 writes data “0” in the register 50 shown in FIG. 5. Accordingly, the sequencer control circuit 30 asserts all of the stop signals SEQ STOP for command sequencers SEQ1 and SEQ3, stop signal SEQ2_STOP for command sequencer SEQ2, and stop signal SEQ4_STOP for command sequencer SEQ4 (i.e., makes all these signals high). In this case, the data transfer controller 13 executes the operation procedure shown in FIG. 1. Thus, in accordance with the data set in the register 50 by the CPU 22, it is possible to switch, if an interrupt occurs because of a read error, a first mode in which data transfer between the NAND flash memory 11 and system bus 20 is continued, and a second mode in which data transfer between the NAND flash memory 11 and system bus 20 is stopped.

### (Effects)

In this embodiment as described in detail above, the memory system 10 includes the data transfer controller 13 which includes the command sequencer group 31 and executes data transfer between the NAND flash memory 11 and system bus 20 by hardware processing different from firmware processing performed by the CPU 22, and the interrupt circuit 21 which requests the CPU 22 to generate an interrupt if a read error occurs. If an interrupt occurs because of a read error, only the operation of command sequencer SEQ4 for performing data transfer between the first memory buffer 15 and ECC decoder 17 is stopped, and the operations of command sequencers SEQ1 to SEQ3 pertaining to the rest of data read are continued.

In this embodiment, therefore, command sequencers SEQ1 to SEQ3 can continue data transfer even while the CPU 22 is performing the interrupt response process. This makes it possible to shorten the latency in the read operation of the NAND flash memory 11. Accordingly, the performance of access to the NAND flash memory 11 can be improved.

Also, even when an interrupt occurs because of a read error, command sequencers SEQ1 to SEQ3 need not be reset after the interrupt response process by the CPU 22. Since this can reduce the firmware processing by the CPU 22, the performance of access to the NAND flash memory 11 can be improved.

In addition, if an interrupt occurs because of a read error, it is possible, by setting data in the register 50 of the sequencer control circuit 30, to switch the first mode in which data transfer between the NAND flash memory 11 and system bus 20 is continued, and the second mode in which data transfer between the NAND flash memory 11 and system bus 20 is stopped.

Furthermore, the processing load on the CPU 22 can be reduced because the data transfer controller 13 performs data transfer between the NAND flash memory 11 and system bus 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory configured to store data;
a first buffer configured to temporarily store data transferred from the nonvolatile memory;
a correction circuit configured to correct an error of data transferred from the first buffer;
a second buffer configured to temporarily store data transferred from the correction circuit;
a bus configured to receive data transferred from the second buffer;
a command sequencer group configured to issue commands for data transfer between the nonvolatile memory and the bus;
a command decoder group configured to decode the commands, and generate control signals for controlling data transfer;
a CPU connected to the bus; and
an interrupt circuit configured to generate an interrupt in the CPU if a read error occurs because of an error correction failure,
wherein the command sequencer group continues data transfer from the nonvolatile memory even when an interrupt occurs because of the read error.

2. The memory system of claim 1, wherein the command sequencer group comprises:
a first command sequencer configured to control data transfer from the nonvolatile memory to the first buffer;
a second command sequencer configured to control data transfer from the first buffer to the correction circuit;
a third command sequencer configured to control data transfer from the correction circuit to the second buffer; and
a fourth command sequencer configured to control data transfer from the second buffer to the bus.

3. The memory system of claim 2, further comprising a control circuit configured to continue operations of the first command sequencer, the third command sequencer, and the fourth command sequencer, and stop an operation of the second command sequencer, if the interrupt occurs.

4. The memory system of claim 2, wherein if the interrupt occurs, the first command sequencer continues data transfer from the nonvolatile memory to the first buffer.

5. The memory system of claim 2, wherein if the interrupt occurs, the fourth command sequencer continues an operation of transferring data received by the second buffer before the read error to the bus.

6. The memory system of claim 2, wherein if the interrupt is released, the second command sequencer resumes a transfer operation from the data having the error correction failure.

7. The memory system of claim 1, wherein the correction circuit corrects an error for each frame including a plurality of bits.

8. The memory system of claim 1, wherein the correction circuit changes an error correction method if a read error occurs.

9. The memory system of claim 3, wherein the control circuit has a first mode in which data transfer from the nonvolatile memory is continued if the interrupt occurs, and a second mode in which data transfer from the nonvolatile memory is stopped if the interrupt occurs, and switches the first mode and the second mode.

10. The memory system of claim 9, wherein the control circuit comprises a register in which an operation mode is set, and switches the first mode and the second mode based on data in the register.

11. A data transfer method of a memory system, the memory system comprising:
a nonvolatile memory configured to store data;
a first buffer configured to temporarily store data transferred from the nonvolatile memory;
a correction circuit configured to correct an error of data transferred from the first buffer;
a second buffer configured to temporarily store data transferred from the correction circuit; and
a bus configured to receive data transferred from the second buffer, and
the data transfer method comprising:
issuing command sequences for data transfer between the nonvolatile memory and the bus;
decoding the command sequences to generate control signals for controlling data transfer;
generating an interrupt in a CPU if a read error occurs because of an error correction failure; and
continuing data transfer from the nonvolatile memory even when an interrupt occurs because of the read error.

12. The method of claim 11, wherein the command sequences comprise a first command sequence for controlling data transfer from the nonvolatile memory to the first buffer, a second command sequence for controlling data transfer from the first buffer to the correction circuit, a third command sequence for controlling data transfer from the correction circuit to the second buffer, and a fourth command sequence for controlling data transfer from the second buffer to the bus.

13. The method of claim 12, wherein the continuing data transfer comprises continuing the issue of the first command sequence, the third command sequence, and the fourth command sequence, and stopping the issue of the second command sequence, if the interrupt occurs.

14. The method of claim 12, wherein if the interrupt occurs, the nonvolatile memory continues data transfer to the first buffer in response to the first command sequence.

15. The method of claim 12, wherein if the interrupt occurs, the second buffer continues an operation of transferring data received before the read error to the bus, in response to the fourth command sequence.

16. The method of claim 12, wherein if the interrupt is released, the first buffer resumes a transfer operation from the data having the error correction failure, in response to the second command sequence.

17. The method of claim 11, wherein the correction circuit corrects an error for each frame including a plurality of bits.

18. The method of claim 11, wherein the correction circuit changes an error correction method if a read error occurs.
